(19) United States
(12) Patent Application Publication
(10) Pub. No.: US 2002/0110026 A1
(43) Pub. Date: Aug. 15, 2002

(54) Head suspension assembly with fins

(76) Inventor: Menachem Rafaelof, Superior, CO (US)

Correspondence Address: Deirdre Megley Kvale, Westman, Champlin & Kelly, International Centre, Suite 1600, 900 Second Avenue South, Minneapolis, MN, 55402-3319, US

(21) Appl. No.: 09/953,097

(22) Filed: Sep. 12, 2001

Related U.S. Application Data
(60) Provisional application No. 60/232,036, filed on Sep. 12, 2000.

(51) Int. Cl. G11C 7/00

(52) U.S. Cl. 365/200

(57) ABSTRACT

A head suspension assembly including fins. The fins are coupled to the suspension assembly and supported along the air flow path or in the flow field to provide operating stability. In one embodiment, the gimbal or suspension includes a fin having a height extending outwardly from one of the opposed surfaces of the gimbal or suspension assembly. In another embodiment, fins include a fin span extending outwardly from opposed sides of the gimbal or suspension assembly.

### CROSS-REFERENCE TO RELATED APPLICATION

This application claims priority to U.S. Provisional Application Ser. No. 60/232,036 filed Sep. 12, 2000 and entitled “METHOD FOR REDUCTION OF THE EFFECT OF AIR FLOW TURBULENCE INSIDE DISC DRIVES”.

### FIELD OF THE INVENTION

The present invention relates to a data storage device. In particular, the present invention relates to a head suspension assembly including fins for stability.

### BACKGROUND OF THE INVENTION

Data storage devices store digital information on a rotating disc. Heads are supported relative to the surface of the rotating disc to read data from or write data to the disc. The head includes a magnetic transducer or optical element which is carried on an air bearing slider to form the data head. The air bearing slider is coupled to a suspension a gimbal spring to form a head gimbal assembly. The slider is coupled to a suspension arm of a suspension assembly which supplies a load force to the slider at a load point. The gimbal assembly flexibly supports the air bearing slider relative to the load point of the suspension arm to allow the slider to pitch and roll for read/write operations.

For operation, rotation of the disc creates an air flow or flow field proximate to the disc surface. Air flow along the air bearing surface of the slider creates a hydrodynamic lifting force for proximity or near proximity recording. Air flow proximate to the gimbal or suspension arm can excite or vibrate the gimbal or suspension arm. In particular, perturbation or turbulence in the flow field can induce or excite vibration of the gimbal assembly or suspension arm increasing head-disc spacing modulations or introducing off-track motion to the head which can degrade read-write operations. The present invention addresses these and other problems and offers solutions not previously recognized nor appreciated.

### SUMMARY OF THE INVENTION

The present invention relates to a head suspension assembly including fins. The fins are coupled to the head suspension assembly and supported along the air flow path or in the flow field to provide operating stability. In one embodiment, the suspension assembly includes a fin having a height extending outwardly relative to one of opposed surfaces of the gimbal or suspension arm in the flow path of air flow to the slider to provide an elongated length extending along the air flow path. In another embodiment, fins include a fin span extending outwardly from opposed sides of the suspension assembly. These and various other aspects and features, as well as advantages that characterize the present invention will be apparent upon reading the following detailed description and review of the associated drawings.

### BRIEF DESCRIPTION OF THE DRAWINGS

FIG. 1 is a perspective illustration of a data storage system.

FIG. 2 is a plan view of a suspension assembly including a gimbal assembly.

FIG. 3 is an elevational view of the suspension assembly of FIG. 2.

FIG. 4 is a front view of a head suspension assembly.

FIG. 5 is a plan view of a head suspension assembly including an embodiment of a fin of the present invention.

FIG. 6 is an elevational view of the head suspension assembly and fin embodiment of FIG. 5.

FIG. 6-1 is an elevational view of a fin embodiment extending from the suspension arm.

FIG. 7 is a detailed illustration of portion 7 of FIG. 5 illustrating the embodiment of the fin of FIGS. 5-6.

FIG. 8 is a plan view of a head suspension assembly including an embodiment of fins of the present invention.

FIG. 8-1 is a plan view of a fin embodiment extending from the suspension arm.

FIG. 9 is a front view of the head suspension assembly and fin embodiment of FIG. 8.

### DETAILED DESCRIPTION OF ILLUSTRATIVE EMBODIMENTS

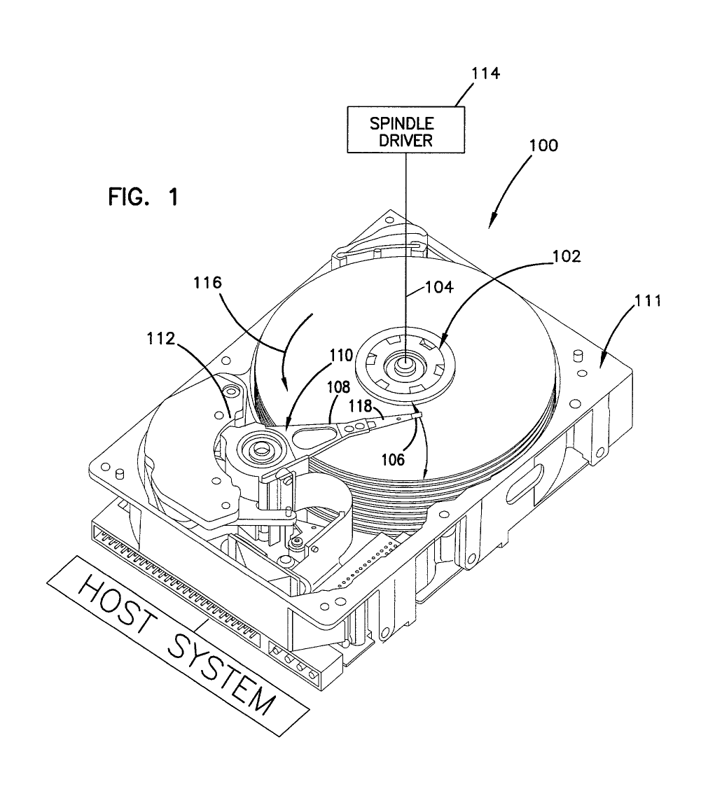

FIG. 1 is an illustrative embodiment of a data storage device 100 including a spindle assembly 102 supporting discs 104 adapted to store digital information. Heads 106 are supported relative to surfaces of the discs 104 to read data from or write data to the discs 104. Heads 106 are coupled to a plurality of actuator arms 108 (only one shown in FIG. 1) of an actuator block 110. The actuator block 110 is powered by a voice coil motor 112 to move heads 104 relative to selective data tracks of the discs 104 for read/write operations. For operation, spindle assembly 102 includes a spindle driver or motor 114 (illustrated diagrammatically) which rotates discs 104 as illustrated by arrow 116.

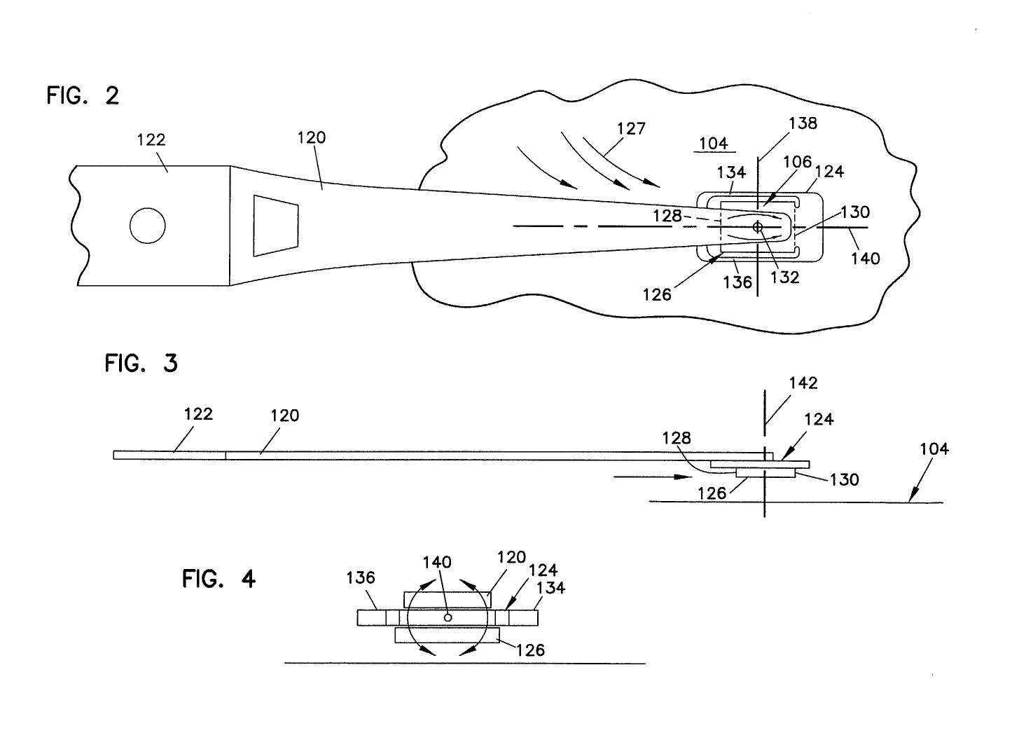

Heads 106 are coupled to the actuator arms 108 of the block 110 via a suspension assembly 118. As shown in FIGS. 2-4, the suspension assembly 118 includes a suspension arm or beam 120 which in the embodiment shown is staked to actuator arms 108 via a mounting plate 122. The head 106 is coupled to the suspension arm 120 through a gimbal spring 124 which allow the head 106 to pitch and roll relative to the disc surface. Thus, the suspension arm 120 and gimbal spring 124 form components of the suspension assembly 118. Head 106 includes an air bearing slider 126 which carries transducer elements, such an inductive, magnetoresistive or magneto-optical transducer elements to read data from or write data to the disc surface.

For operation, rotation of the discs 104 creates an air flow as illustrated by arrows 127 along an air bearing surface (not shown) of the slider which creates a hydrodynamic lifting force. In particular, air flows from a leading edge 128 to a trailing edge 130 of the slider 126. The hydrodynamic lifting force is countered by a load force supplied by the suspension arm 120 to the slider 126 at a load point 132. The gimbal spring 126 includes opposed gimbal arms 134, 136 to flexibly support the slider 126 relative to the load point 132 so that the slider 126 pitches about a pitch axis 138 and rolls about a roll axis 140. Pitch and roll parameters of the slider 126 affect fly height parameters and read write operations of the head.

The slider 126 can also rotate or move about a yaw axis 142 as illustrated in FIG. 3. Movement of the slider 126 relative to the yaw axis 142 introduces off-track motion to the head and affects track seek and following operations. During operation, turbulent or perturbed air flow along the air flow path can vibrate or excite the gimbal assembly or suspension arm. In particular, turbulent or perturbed air flow can excite movement of the head or slider 126 about the roll axis 140 and yaw axis 142. Excitation or movement of the head about the roll axis 140 and yaw axis 142 increases instability of slider introducing fly height modulations or off-track motion to the head.

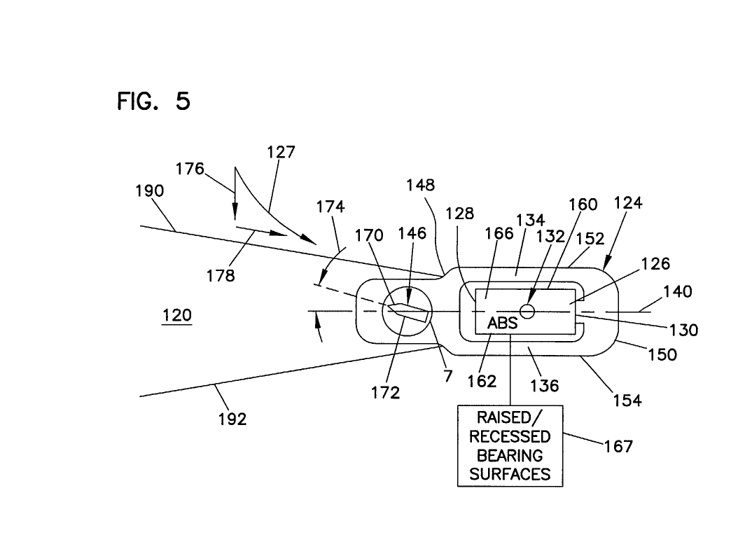

FIGS. 5-7 illustrate an embodiment of a head suspension assembly including fin 146 supported in the air flow path to the slider where like numbers are used to identify like parts in the previous FIGS. FIG. 5 is a plan view of the head suspension assembly from an air bearing direction of the slider. In the embodiment shown, the gimbal spring is separately connected to an extended end of the suspension arm 120, or alternatively, the gimbal spring can be integrally formed with the suspension arm and application is not limited to the particular embodiments shown.

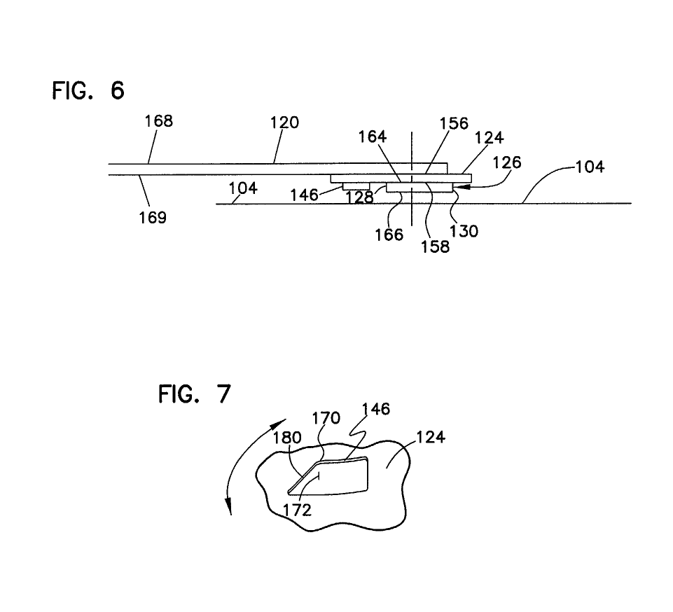

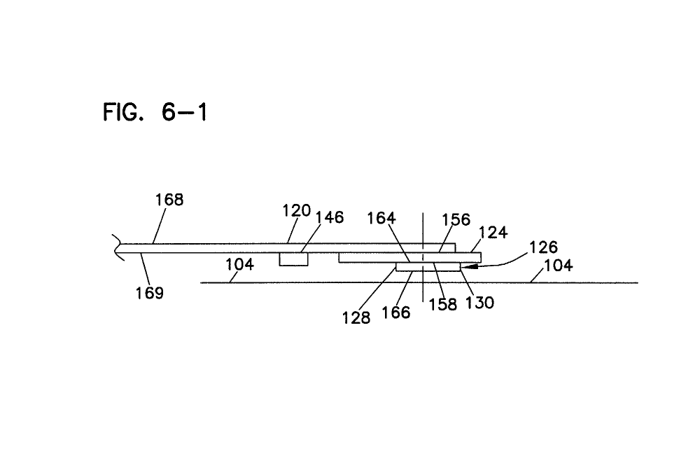

As shown in FIGS. 5-6, the gimbal spring or gimbal assembly 124 includes a leading edge 148, a trailing edge 150, opposed side edges 152, 154 and opposed first and second surfaces 156, 158 as shown in FIG. 6. The slider includes opposed side edges 160, 162, a first surface 164 and an opposed bearing surface 166 including a raised bearing surface and recessed bearing surface as illustrated diagrammatically at block 167. Fin 146 includes a height extending outwardly relative to the second surface 158 of the gimbal spring assembly 124 as shown in FIG. 6 and an elongated length extending along a portion of the suspension assembly in the flow path of air flow to the air bearing slider 126. The fin 146 is shown connected to the second surface 158 of the gimbal spring but alternatively could be connected to a similar second surface 168 of opposed first and second surfaces 168, 169 of the suspension arm 120 as shown in FIG. 6-1. Thus, fin can extend from a second surface of the suspension assembly defined by the second surfaces of the gimbal spring, suspension arm or similar suspension component.

The fin 146 includes opposed first and second flow surfaces 170, 172 having a surface length aligned along the air flow path. In the particular embodiment shown, fin 146 is angled in the direction of the flow path to the slider as illustrated by angle 174. In particular, air flow as illustrated by arrow 127 in the flow field includes a radial velocity component vᵣ 176 and a tangential velocity component vₜ 178. The incline angle 174 of the fin 146 in the direction of the air flow in the flow path is determined based upon:

$$Θ ( 174 ) = {Tan}^{- 1} ( \frac{{V}_{r}}{{V}_{t}} )$$

Also in the embodiment shown, fin 146 includes a sloped leading portion 180 as shown in FIG. 7. The fin 146 is aligned to control stability of the suspension, for example to control stability relative to the roll 140 and/or yaw axis 142. Although a particular shape and configuration of the fin 146 is shown, application is not limited to any particular shape or configuration and various shape can be used to provide desired flow dynamics

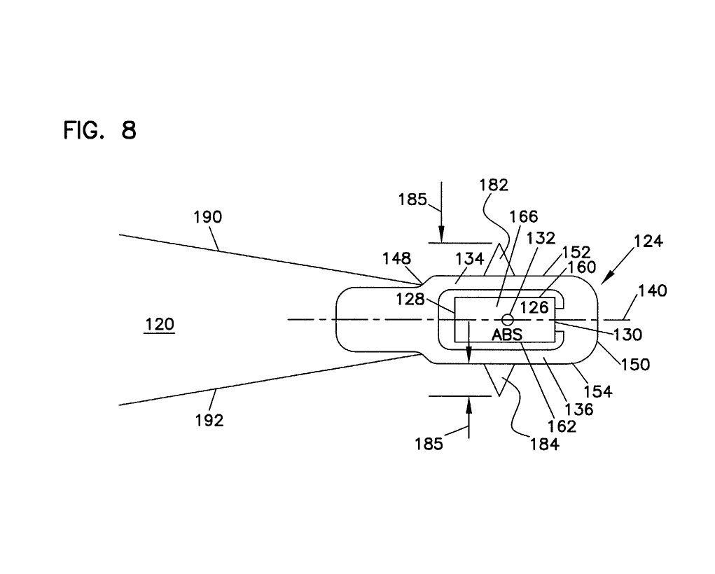

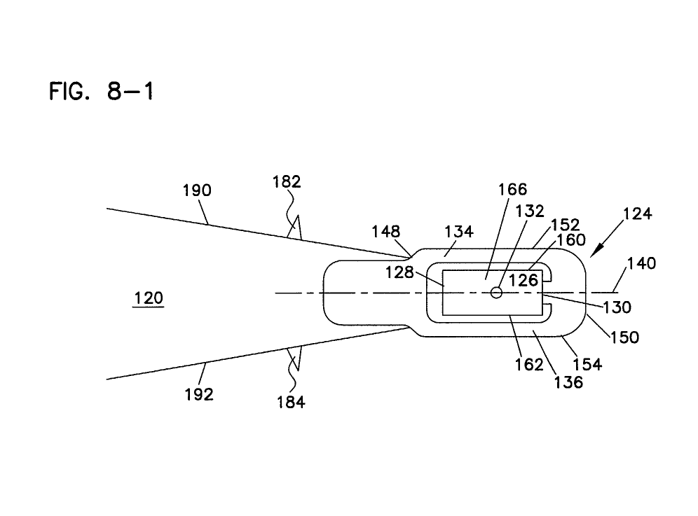

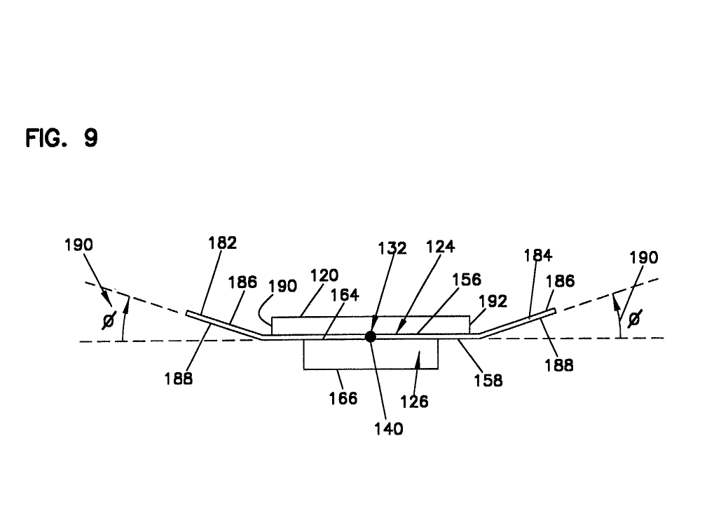

FIGS. 8-9 illustrate an embodiment of a head suspension assembly including fins 182, 184 where like numbers are used to identify like parts in the previous FIGS. In the embodiment shown, the fins 182, 184 extend outwardly from opposed sides 152, 154 of the gimbal spring or gimbal arms 134, 136 of the suspension assembly along a fin span 185. As shown a width of the fins is tapered along the fin span 185. The fins 182, 184 include opposed flow surfaces 186, 188 as illustrated in FIG. 9.

The fins 182, 184 are supported in the flow path to reduce flow-induced excitation of the suspension components, for example, relative to the roll axis 140. In the particular embodiment illustrated, fins 182, 184 are oriented at a dihedral angle 190 relative to the plane of the gimbal spring for roll stability. Alternatively fins 182, 184 can extend outwardly from opposed sides 192, 194 of the suspension arm 120 of the suspension assembly in the flow path to the slider as shown in FIG. 8-1. Thus, fins can extend from opposed sides of the suspension assembly defined by the opposed sides of the gimbal spring, suspension arm or other suspension component.

A head suspension assembly including fins (such as 146, 182, 184). In one embodiment, the suspension assembly includes a fin (such as 146) having a height extending outwardly relative to one of the opposed surfaces of the gimbal spring or suspension assembly to provide an elongated length along the air flow path. In another embodiment, fins (such as 182, 184) include a fin span extending outwardly relative to opposed sides of the gimbal spring or suspension assembly.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application for head gimbal assembly while maintaining substantially the same functionality without departing from the scope and spirit of the present invention. In addition, although the preferred embodiment is described with reference to a magnetic disc drive system, it will be appreciated by those skilled in the art that the teachings of the present invention can be applied to other drive systems, such as optical systems, without departing from the scope and spirit of the present invention.

What is claimed is:

1. A head suspension assembly comprising:
a gimbal assembly having opposed first and second surfaces and side edges and including opposed gimbal arms;
an air bearing slider coupled to the gimbal assembly and having a leading edge, a trailing edge and opposed side edges and a first surface and a second opposed air bearing surface including at least one raised bearing surface and at least one recessed bearing surface;
a suspension arm having opposed surfaces and opposed side edges and adapted to supply a load force to the slider and the gimbal assembly and suspension arm cooperatively forming a suspension assembly having opposed surfaces and opposed side edges defined by the opposed surfaces and side edges of the gimbal assembly and suspension arm; and
at least one fin having a height extending outwardly relative to the second surface of the suspension assembly in an air flow path to the slider and the fin having an elongated length extending along a length portion of the suspension assembly along the air flow path to the slider.

2. The head suspension assembly of claim 1 wherein the at least one fin is orientated at an angle relative to the suspension assembly in alignment with the air flow path to the slider.

3. The head suspension assembly of claim 1 wherein the angle is defined by (Θ=Tan⁻¹(vᵣ/vₜ) where Θ is the angle, vᵣ is a radial velocity component and vₜ is a tangential velocity component of air flow induced by rotation of a data disc.

4. The head suspension assembly of claim 1 wherein the fin includes a sloped leading edge.

5. The head suspension assembly of claim 1 wherein the elongated length of the fin is parallel to a yaw axis of the head gimbal assembly.

6. The head suspension assembly of claim 1 wherein the fin is connected to and extends from the second surface of the gimbal assembly.

7. The head suspension assembly of claim 1 wherein the fin is connected to and extends from the second surface of the suspension arm.

8. A head suspension assembly comprising:
a gimbal assembly having opposed first and second surfaces and opposed side edges and including opposed gimbal arms;
an air bearing slider coupled to the gimbal assembly and having a leading edge, a trailing edge and opposed side edges and a first surface and a second opposed air bearing surface including at least one raised bearing surface and at least one recessed bearing surface;
a suspension arm having opposed surfaces and opposed side edges and adapted to supply a load force to the slider and the gimbal assembly and suspension arm cooperatively forming a suspension assembly having opposed surfaces and opposed side edges defined by the opposed surfaces and side edges of the gimbal assembly and suspension arm; and
fins having a fin span extending outwardly from the opposed first side edges of the suspension assembly.

9. The head suspension assembly of claim 8 wherein a width of the fins is tapered along the fin span of the fins.

10. The head suspension assembly of claim 8 wherein the fins are supported at a dihedral angle relative to a plane of the gimbal assembly.

11. The head suspension assembly of claim 8 wherein the fins are connected to and extend outwardly from opposed sides of the gimbal assembly.

12. The head suspension assembly of claim 8 wherein the fins are connected to and extend outwardly from opposed sides of the suspension arm.

13. A head suspension assembly comprising:
a suspension assembly including a suspension arm and a gimbal spring including opposed gimbal arms and a slider coupled to the gimbal spring; and
fin means for controlling stability of the slider coupled to the gimbal spring.

14. The head suspension assembly of claim 13 wherein the fin means for controlling stability controls rolls stability.

15. The head suspension assembly of claim 13 wherein the fin means for controlling stability controls yaw stability.

16. The head suspension assembly of claim 13 wherein the gimbal spring includes a leading edge, a trailing edge and opposed side edges and a first surface and a second surface and the fin means for controlling stability includes a fin having a height extending outwardly from the second surface of the gimbal spring and having an elongated length extending along a portion of a length of the gimbal spring between the leading edge and the trailing edge of the gimbal spring.

17. The head suspension assembly of claim 13 wherein the suspension arm includes opposed side edges and a first surface and a second surface and the fin means for controlling stability includes a fin having a height extending outwardly from the second surface of the suspension arm and having an elongated length extending along a portion of a length of the suspension arm.

18. The head suspension assembly of claim 13 wherein the gimbal spring includes a leading edge, a trailing edge and opposed side edges and a first surface and a second surface and the fin means for controlling stability includes fins having a fin span extending outwardly from the opposed side edges of the gimbal spring.

19. The head suspension assembly of claim 13 wherein the suspension arm includes opposed side edges and a first surface and a second surface and the fin means for controlling stability includes fins having a fin span extending outwardly from the opposed side edges of the suspension arm.
